(19) United States
(12) Patent Application Publication
(10) Pub. No.: US 2009/0045439 A1
(43) Pub. Date: Feb. 19, 2009

(54) Heterojunction field effect transistor and manufacturing method thereof

(75) Inventors: Shinichi Hoshi, Tokyo (JP); Isao Tamai, Tokyo (JP); Fumihiko Toda, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/219,040

(22) Filed: Jul. 15, 2008

(30) Foreign Application Priority Data
Aug. 17, 2007 (JP) 2007-212750

(51) Int. Cl. H01L 29/778; H01L 21/31

(52) U.S. Cl. 257/194; 438/780; 257/E29.247; 257/E21.24

(57) ABSTRACT

A heterojunction field effect transistor includes a laminated body. The laminated body includes a channel layer of GaN, an electron supply layer of AlN or AlₓGa₁₋ₓN (0.6≦x<1) formed on the channel layer, and a cap layer of GaN formed on the electron supply layer.

### BACKGROUND OF THE INVENTION

This invention relates to a heterojunction field effect transistor and a manufacturing method thereof, and particularly relates to a heterojunction field effect transistor having an electron supply layer of an AlN or AlₓGa₁₋ₓN (0.6≦x<1) and a manufacturing method thereof.

A conventional heterojunction field effect transistor will be described with reference to FIG. 11. FIG. 11 is a sectional view schematically showing a conventional heterojunction field effect transistor.

The heterojunction field effect transistor 110 includes a substrate 120, a channel layer 140 of GaN formed on the substrate 120, and an electron supply layer 150 of AlGaN formed on the channel layer 140. The heterojunction field effect transistor 110 has a heterostructure of the channel layer 140 (GaN) and the electron supply layer 150 (AlGaN). With such a structure, it is possible to obtain high density two-dimensional electron gas (2DEG) and high electron mobility at a heterointerface 142 between the channel layer 140 and the electron supply layer 150, and the heterojunction field effect transistor 110 shows excellent performance as a high electron mobility transistor. Hereinafter, the high electron mobility transistor, i.e., the heterojunction field effect transistor having AlGaN/GaN heterostructure is also referred to as HEMT (High Electron Mobility Transistor).

A source electrode 182 and a drain electrode 184 are formed in ohmic contact with the electron supply layer 150. A gate electrode 180 is formed in schottky contact with the electron supply layer 150. The AlGaN/GaN-HEMT 110 is isolated from other element by an element isolation region 135 formed by, for example, injecting impurities into the channel layer 140 and the electron supply layer 150. A surface protection film 190 of silicon nitride is formed on an upper surface 152 of the electron supply layer 150.

In this regard, in the case where the electron supply layer 150 is composed of AlₓGa₁₋ₓN (x=0.25), the density of 2DEG is 1.0×10³ cm⁻² and the electron mobility is 1500 cm²/V·s when the thickness of the electron supply layer (i.e., the active layer thickness “a”) is 25 nm.

In order to accomplish a higher frequency FET, it is effective to increase cutoff frequency. Further, in order to increase cutoff frequency, it is most effective to reduce a gate length Lg.

However, the reduction of the gate length Lg may cause a “short channel effect” such as a degradation of pinch-off characteristics, a negative shift of threshold voltage or the like. The degradation of pinch-off characteristics causes a reduction of operation voltage of the FET. Further, the shift of threshold voltage narrows the tolerance with respect to the design value, and affects the yield rate or the like.

In order to prevent such a short channel effect, it is preferable that a ratio (i.e., an aspect ratio) Lg/a of the gate length Lg to the active layer thickness “a” is greater than or equal to 5 (see, for example, Non-Patent Document No. 1).

The above described AlGaN/GaN-HEMT 110 has the active layer thickness (a) of 25 nm, and therefore the aspect ratio Lg/a is approximately 4 in a short gate region where the gate length Lg is 0.1 μm. Accordingly, the short channel effect occurs.

Here, when the active layer thickness (a) is reduced and the thickness of the electron supply layer 150 is reduced, 2DEG density is also reduced. In contrast, when “x” in the AlₓGa₁₋ₓN (i.e., the concentration of Al) is increased toward 1 (i.e., AlN), the thickness of the electron supply layer 150 can theoretically be ¼ compared with the AlₓGa₁₋ₓN (x=0.25). However, in the case where AlₓGa₁₋ₓN is grown using MOCVD (Metal Organic Chemical Vapor Deposition) method, if the concentration of Al in the AlₓGa₁₋ₓN is increased, cracks may occur on the surface of the AlₓGa₁₋ₓN layer when x is approximately 0.52, and affect the FET characteristics (see, for example, Non-Patent Document No. 2).

Further, it is known that gate leak characteristics may be deteriorated due to surface oxidation (see, for example, Non-Patent Document No. 3).

Similarly, in the case where AlN is grown using MOCVD method, cracks may occur on the surface of the AlN layer even when the thickness of the AlN layer is approximately 2 nm.

For these reasons, neither AlN nor AlₓGa₁₋ₓN (x≧0.6) can be used as the electron supply layer 150.

It is considered that the occurrence of cracks on the surface of the AlN layer is caused by a difference between thermal expansion coefficients of GaN and AlN during the temperature falling after the MOCVD process for growing the AlN layer at high temperature (1200° C.), or caused by the oxidation of AlN when exposed to the atmosphere. However, the exact reason has not yet been revealed.

There is known a method performing PAMBE (Plasma Assisted Molecular Beam Epitaxy) process to thereby form the AlN layer (see, Non-Patent Document No. 4).

Non-Patent Document No. 4 describes that, using the PAMBE process, AlN is grown at a low temperature in a range from 200 to 300° C., and therefore the AlN layer can be grown without occurrence of cracks.

[Non-Patent Document No. 1] Masumi Fukuda, Yasuo Hirachi, “Basis for GaAs Field Effect Transistor”, Corona Publishing Co. Ltd., 1992, pp 56-59.

[Non-Patent Document No. 2] Makoto Miyoshi et al., “Characterization of Different-Al-Content AlGaN/GaN Heterostructures and High-Electron-Mobility Transistors Grown on 100-mm-Diameter Sapphire Substrates by Metalorganic Vapor Phase Epitaxy”, Jpn. J. Appl. Phys., Vol. 43, No. 12, 2004, pp. 7939-7943.

[Non-Patent Document No. 3] Tamotsu Hashizume et al., “Surface Control Process of AlGaN for Suppression of Gate Leakage Currents in AlGaN/GaN Heterostructure Field Effect Transistors”, Jpn. J. Appl. Phys., Vol. 45, No. 4, 2006, pp. L11-L113.

[Non-Patent Document No. 4] Masataka Higashiwaki et al., “Al/GaN Insulated-Gate HFETs Using Cat-CVD SiN”, IEEE ELECTRON DEVICE LETTERS, Vol. 27, No. 9, 2006, pp. 719-721.

[Non-Patent Document No. 5] Takahiko Iwasaki et al., “Study on Crystal Growth of AlGaN/GaN HEMT on SiC Substrate”, Technical Report of IEICE, ED2006-155, CPM2006-92, LQE2006-59 (2006-10), pp. 19-22.

In the case where an AlN layer is used as an electron supply layer, it is preferable that the AlN layer is thicker than 2 nm and at least in a range approximately from 4 to 5 nm, in order to increase 2DEG density.

However, although Non-Patent Document No. 3 discloses a method of forming the AlN layer having the thickness of approximately 2.5 nm, no report has been made on the formation of the AlN layer thicker than 2.5 nm.

Further, it is studied to use the AlN layer as a spacer layer (see, for example, Non-Patent Document No. 5). The Non-Patent Document No. 5 discloses a technique forming a GaN layer (as a channel layer), an AlN layer (as a spacer layer) and an AlGaN layer (as an electron supply layer) on a substrate using MOCVD method.

However, Non-Patent Document No. 5 describes that the optimum thickness of the AlN layer (the spacer layer) is approximately 1 nm. The formation of the AlN layer thicker than 2 nm is not studied in the Non-Patent Document No. 5.

Therefore, inventors of the present application have conducted dedicated study, and have found that, by forming a GaN layer as a cap layer using MOCVD method following the formation of the AlN layer (as an electron supply layer), the occurrence of cracks can be prevented and a flat surface can be obtained even when the thickness of the AlN layer is thicker than 2.5 nm.

### SUMMARY OF THE INVENTION

The present invention is intended to solve the above described problems, and an object of the present invention is to provide a heterojunction field effect transistor having an electron supply layer of AlN or AlₓGaN (0.6≦x<1), and a manufacturing method thereof.

The present invention provides a heterojunction field effect transistor including a laminated body including a channel layer of GaN, an electron supply layer of AlN or AlₓGa₁₋ₓN (0.6≦x<1) and a cap layer of GaN. The channel layer, the electron supply layer and the cap layer are laminated.

The present invention also provides a manufacturing method of a heterojunction field effect transistor as follows. First, a channel layer of GaN is formed on a substrate. Next, an electron supply layer of AlN or AlₓGa₁₋ₓN (0.6≦x<1) is formed on the channel layer. Next, a cap layer of GaN is formed on the electron supply layer. The formation of the channel layer, the electron supply layer and the cap layer are performed using MOCVD method in the same equipment.

The present invention also provides a manufacturing method of a heterojunction field effect transistor as follows. First, a channel layer of GaN is formed on a substrate. Next, an electron supply layer of AlN or AlₓGa₁₋ₓN (0.6≦x<1) is formed on the channel layer. Next, a gate insulation film of silicon nitride is formed on the electron supply layer. The formation of the channel layer, the electron supply layer and the gate insulation film are performed using MOCVD method in the same equipment.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

In the attached drawings:

FIG. 1 is a sectional view schematically showing a heterojunction field effect transistor according to the first embodiment of the present invention;

FIG. 2 is a view showing a surface of an electron supply layer (an AlN layer) formed by a conventional method, observed using an atomic force microscope;

FIG. 3 is a view showing a surface of a cap layer (a second GaN layer) according to the first embodiment, observed using the atomic force microscope;

FIGS. 4A through 4F are views showing a surface of the cap layer (the second GaN layer) observed using atomic force microscope when the thickness of AlN layer is varied;

FIG. 5 is a view showing the relationship between the thickness and RMS of surface roughness of the electron supply layer (the AlN layer);

FIG. 6 is a view showing a measurement result of carrier concentration by means of C-V measurement in the first embodiment;

FIG. 7 is a sectional view schematically showing a heterojunction field effect transistor according to the second embodiment;

FIG. 8 is a view showing a measurement result of carrier concentration by means of C-V measurement in the second embodiment;

FIGS. 9A and 9B are views showing gate leak current characteristics of the heterojunction field effect transistor;

FIG. 10 is a sectional view schematically showing a heterojunction field effect transistor according to the third embodiment, and

FIG. 11 is a sectional view schematically showing a conventional heterojunction field effect transistor.

### DETAILED DESCRIPTION OF THE PREFERRED EMBODIMENT

Hereinafter, an embodiment of the present invention will be described with reference to the attached drawings. Shapes, sizes and positions of respective components are schematically shown in the attached drawings merely for the illustrative purpose, but do not limit the scope of the present invention. Specific materials, conditions, numerical examples or the like described in the following description are merely preferred examples, but do not limit the scope of the present invention. The present invention is not limited to the following embodiments, but modifications and improvements may be made to the invention without departing from the scope of the invention so as to obtain the effect of the invention.

### First Embodiment

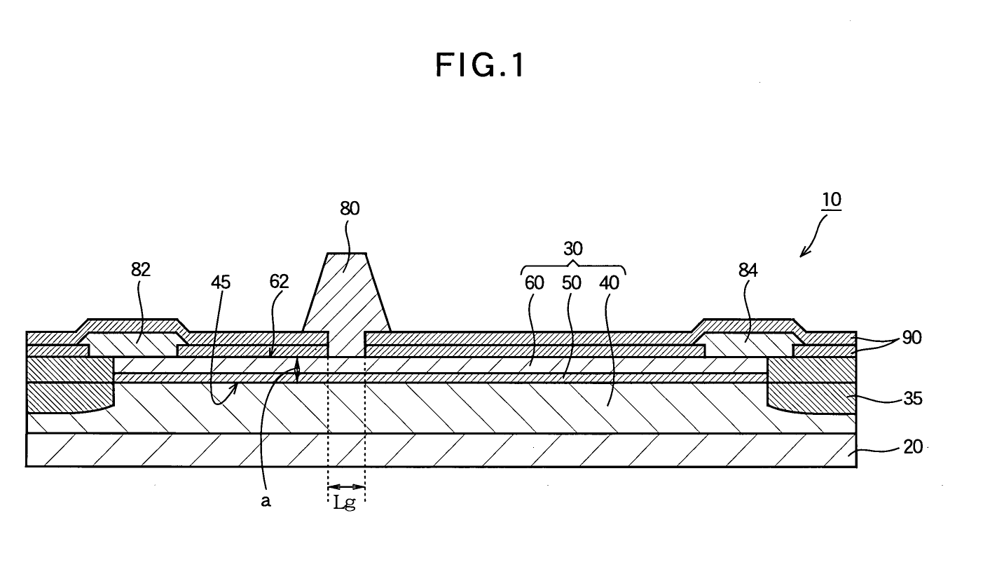

The heterojunction field effect transistor of the first embodiment will be described with reference to FIG. 1. The heterojunction field effect transistor is a high electron mobility transistor (HEMT). Therefore, in the following description, the heterojunction field effect transistor is also referred to as HEMT.

FIG. 1 is a sectional view schematically showing the heterojunction field effect transistor according to the first embodiment.

The heterojunction field effect transistor 10 according to the first embodiment includes a substrate 20 and a laminated body 30 formed on the substrate 20. The laminated body 30 includes a channel layer of GaN (i.e., a first GaN layer), an electron supply layer 50 of AlN (i.e., an AlN layer) and a cap layer 60 of GaN (i.e., a second GaN layer) laminated in this order on the substrate 20. Two dimensional electron gas (2DEG) is formed at an AlN/GaN heterointerface 45 between the channel layer 40 (the first GaN layer) and the electron supply layer 50 (the AlN layer).

A source electrode 82 and a drain electrode 84 (i.e., first and second main electrodes) are formed in ohmic contact with the cap layer 60. Further, a gate electrode (i.e., a control electrode) 80 is formed in schottky contact with the cap layer 60. The AlN/GaN-HEMT 10 is isolated from other element by an element isolation region 35 formed by, for example, injecting impurities into the channel layer 40 and the electron supply layer 50. A surface protection film 90 of silicon nitride (i.e., a silicon nitride film) is formed on the surface of the upper surface 152 of the electron supply layer 50.

The heterojunction field effect transistor 10 is manufactured as follows.

First, a substrate 20 is prepared. The structure of the substrate 20 can be the same as a substrate used in a conventional heterojunction field effect transistor. For example, it is possible to use a base composed of material selected among silicon, silicon carbide and sapphire, on which a buffer layer is formed. The buffer layer is provided for inducing lattice relaxation between the base (silicon or the like) and the channel layer 40 formed on the substrate 20. The buffer layer is formed by, for example, growing AlN using MOCVD (Metal Organic Chemical Vapor Deposition) method.

Next, the channel layer 40 (i.e., the first GaN layer) is formed on the substrate 20. Then, the electron supply layer 50 (i.e., the AlN layer) is formed on the channel layer 40. Then, the cap layer 60 (i.e., the second GaN layer) is formed on the electron supply layer 50.

Here, the channel layer 40, the electron supply layer 50 and the cap layer 60 are laminated using the MOCVD method in the same equipment. The electron supply layer 50 (i.e., the AlN layer) is formed at the growing temperature of 1200° C. while introducing ammonium (NH₃) gas and trimethyl aluminum (TMA) respectively at flow rates of 6 slm and 10 sccm into the CVD equipment (to be more specific, the MOCVD equipment). Each of the channel layer 40 (the first GaN layer) and the cap layer 60 (the second GaN layer) is formed at the growing temperature of 1070° C. while introducing ammonium (NH₃) gas and trimethyl gallium (TMG) gas respectively at flow rates of 5 slm and 6 sccm into the MOCVD equipment. In this regard, sccm (standard cubic cm per minute) and slm (standard liter per minute) are units of gas flow converted at standard condition (i.e., 0° C. and 1 atmospheric pressure (1013 hPa)).

In this regard, the electron supply layer 50 (i.e., the AlN layer) contains a large amount of Al, and is subject to the surface oxidation, i.e., is likely to induce cracks. For this reason, if the electron supply layer 50 (the AlN layer) is exposed to the atmosphere, the controlling of the gate leak current becomes difficult. In the manufacturing method of the heterojunction field effect transistor according to the first embodiment, the electron supply layer 50 (the AlN layer) is covered with the cap layer 60 (the second GaN layer), and therefore the oxidation of the electron supply layer 50 can be prevented.

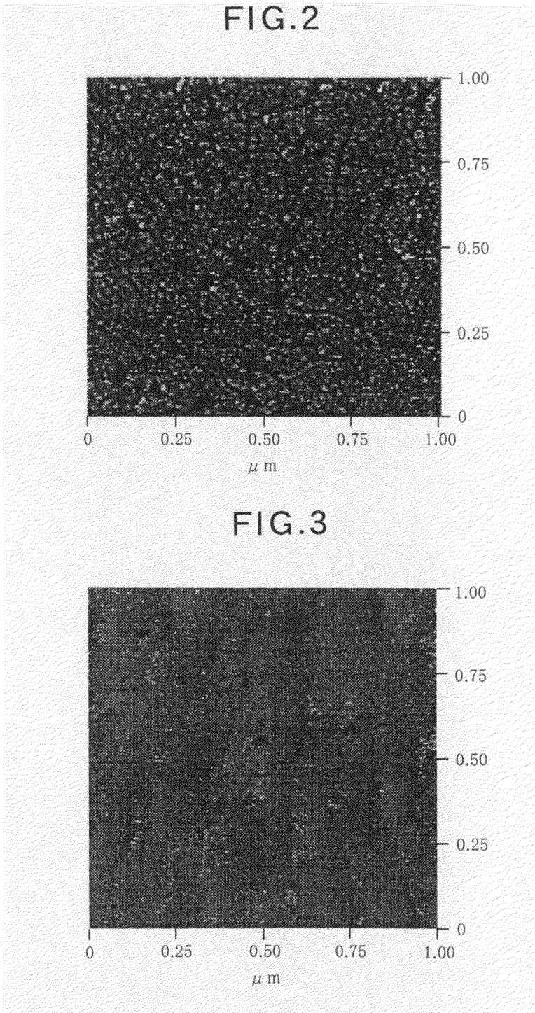

FIG. 2 shows the surface of an electron supply layer (an AlN layer) formed by a conventional method using MOCVD to the thickness of 2 nm, observed using an atomic force microscope (AFM). FIG. 3 shows the surface of the cap layer 60 (the second GaN layer) formed following (i.e., continuously subsequent to) the formation of the electron supply layer 50 (the AlN layer) according to the first embodiment, observed using the AFM. Each of FIGS. 2 and 3 shows an area of 1 μm square.

In FIG. 2, cracks are observed on the surface of the electron supply layer (the AlN layer). In contrast, in FIG. 3, no crack is observed on the surface of the cap layer 60 (the second GaN layer), and therefore it is understood that the electron supply layer 50 (under the cap layer 60) has an excellent surface structure. To be more specific, if cracks occur on the electron supply layer 50, the cracks may affect the surface of the cap layer 60 (the second GaN layer). However, in FIG. 3, no cracks are observed on the surface of the cap layer 60. Therefore, it is understood that the occurrence of cracks on the surface of the electron supply layer 50 (the AlN layer) is prevented by the formation of the cap layer 60 (the second GaN layer) following the formation of the electron supply layer 50 using the MOCVD method in the same equipment.

In the case where the growing process is terminated at a step where the electron supply layer (the AlN layer) is formed, cracks are observed (using the AFM) on the surface of the electron supply layer as shown in FIG. 2. From this result, it is understood that the occurrence of cracks on the surface of the electron supply layer 50 (the AlN layer) is prevented (FIG. 3) by the formation of the cap layer 60 (the second GaN layer) following the formation of the electron supply layer 50. The exact reason thereof has not been clear, but several possible reasons can be made. One possible reason is that the structure in which the first and second GaN layers (the channel layer 40 and the cap layer 60) sandwich the electron supply layer 50 (the AlN layer) prevents the breaking of the electron supply layer 50. Another possible reason is that the cap layer 60 (the second GaN layer) covering the electron supply layer 50 (the AlN layer) prevents the oxidation of the electron supply layer 50 so as to prevent the occurrence of cracks due to the oxidation.

After the electron supply layer 50 (the AlN layer) is grown at the temperature of 1200° C., no crack occurs on the surface of the electron supply layer 50 at the step where the temperature is lowered to 1070° C. (for growing the cap layer 60) and at the step of growing the GaN layer as the cap layer 60. Further, after the cap layer 60 is grown, the flatness of the surface can be maintained even when the temperature is lowered to room temperature.

For example, when the thickness of the electron supply layer 50 is set to 2.5 nm and the thickness of the cap layer 60 is set to 5 nm, the active layer thickness (a) is 7.5 nm. In this case, the aspect ratio (Lg/a) can be greater than or equal to 5 (and therefore the short channel effect can be prevented), even when the gate length (Lg) is shortened to 40 nm.

In order to increase 2DEG density, it is preferable to increase the thickness of the electron supply layer 50 (the AlN layer). The lattice constants of AlN and GaN are respectively 3.112 Å and 3.187 Å, and the difference therebetween is 2.4%. A critical thickness of the electron supply layer 50 in which the electron supply layer 50 can be formed without occurrence of cracks is theoretically 10 nm.

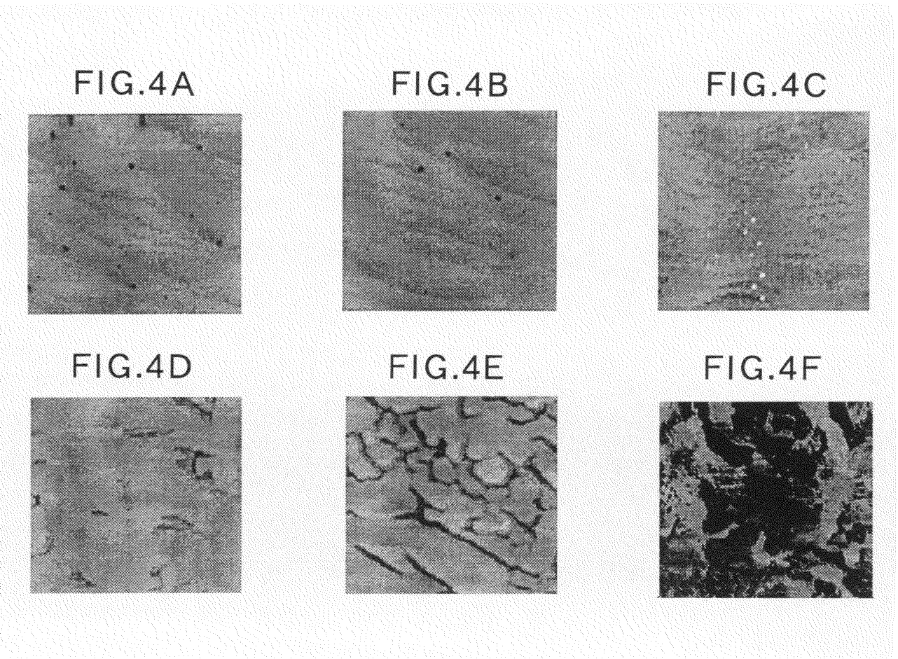

FIGS. 4A, 4B, 4C, 4D, 4E and 4F show images taken by the AFM when the thickness of the AlN layer is respectively 0.5 nm, 2.5 nm, 2.55 nm, 6.08 nm, 8.12 nm and 20 nm. FIGS. 4A through 4F show images of the area of 1 μm square taken by the AFM on the surface of the cap layer 60 (the second GaN layer) formed on the electron supply layer 50 (the AlN layer).

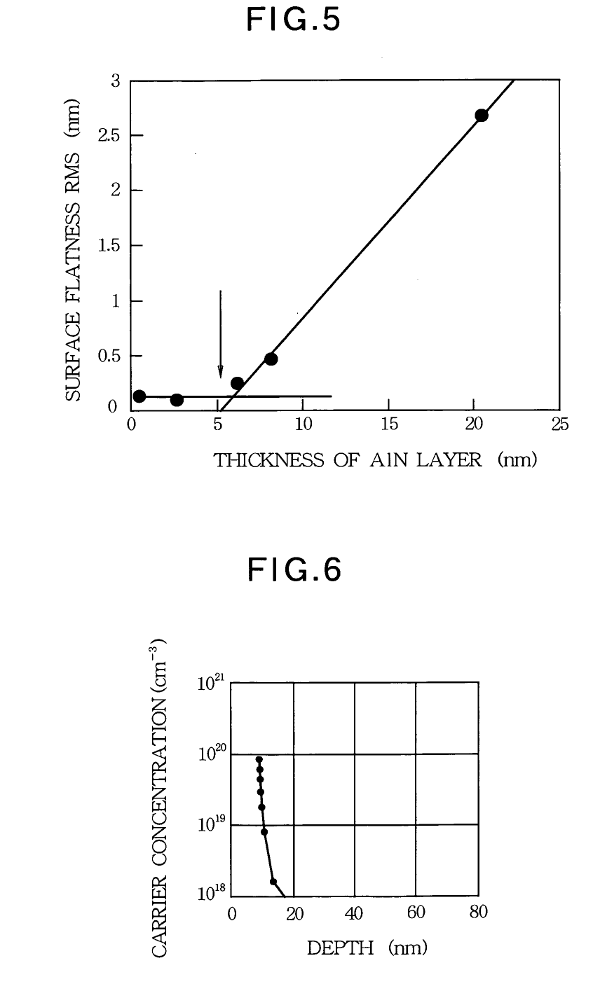

FIG. 5 shows the relationship between the thickness of the electron supply layer 50 (the AlN layer) and the flatness of the surface of the cap layer 60 (the second GaN layer). In FIG. 5, the horizontal axis represents the thickness of the AlN layer (unit: nm), i.e., the electron supply layer 50. The vertical axis represents RMS, (root means square) of surface roughness (unit: nm). The RMS of surface roughness, which is used to evaluate the flatness, is determined by a distribution of heightwise positions on a surface, and is calculated by square means of heightwise positions as differences from an average heightwise position.

When the thickness of the electron supply layer 50 (the AlN layer) is thinner than or equal to 2.55 nm, no crack occurs on the surface of the electron supply layer 50, and the RMS is less than or equal to 0.2 nm. When the thickness of the electron supply layer 50 is 6.08 nm, cracks occur on the surface of the electron supply layer 50. As the thickness of the electron supply layer 50 further increases, the occurrence of cracks becomes prominent.

In a region where the thickness of the electron supply layer 50 (the AlN layer) is thicker than or equal to 6.08 nm, the RMS increases as a linear function. In other words, the increase of the RMS corresponds to the increase of cracks. In contrast, the RMS is constant in a region where the thickness of the electron supply layer 50 (the AlN layer) is thinner than or equal to 2.55 nm.

In a region where the thickness of the electron supply layer 50 (the AlN layer) is thicker than or equal to 6.08 nm, the relationship between the thickness (x) of the electron supply layer 50 and the RMS (y) can be approximated by the linear function y=0.18x−0.89, i.e., y becomes 0 when x is approximately 5. Therefore, it is considered that the influence of cracks on the operation of FET can be ignored when the thickness of the electron supply layer 50 (the AlN layer) is thinner than or equal to 5 nm.

FIG. 6 shows a measurement result of carrier concentration measured by C-V (Capacitance-Voltage) measurement using mercury probe. In FIG. 6, the horizontal axis represents a depth (unit: nm) with respect to the bottom surface of the gate electrode 80 (i.e., the upper surface of the laminated body 30). The vertical axis represents carrier concentration (unit: cm⁻³). FIG. 6 shows a measurement result in the case where the thickness of the electron supply layer 50 (the AlN layer) is 2.5 nm and the cap layer 60 (the GaN layer) is 5 nm. As shown in FIG. 6, the existence of carrier having the concentration of 8.6×10¹⁹ cm⁻³ is recognized at the depth of 9 nm.

Similar measurements are performed while varying the thickness of the electron supply layer 50 (the AlN layer). When the thickness of the electron supply layer 50 is 0.5 nm, the existence of carrier is not recognized. When the thickness of the electron supply layer 50 is in a range from 2.5 nm to 20 nm, the existence of carrier is recognized.

From these results, a preferable range of the thickness of the electron supply layer 50 (the AlN layer) is from 2.5 nm to 5 nm, in consideration of the existence of the carrier and the RMS of the surface roughness.

Next, the use of an AlₓGa₁₋ₓN layer as the electron supply layer 50 will be described.

When x of the AlₓGa₁₋ₓN (i.e., the concentration of Al) is increased to 1, AlₓGa₁₋ₓN becomes AlN. It is known that cracks may occur on AlₓGa₁₋ₓN when x is greater than or equal to 0.52 (see, Non-Patent Document No. 2).

Here, it is derived that the GaN cap layer 60 (effectively prevents the occurrence of cracks on the AlN layer) also effectively prevents the occurrence of cracks on the AlₓGa₁₋ₓN layer (0.6≦x<1). For this reason, the AlₓGa₁₋ₓN layer (0.6≦x<1) can be used as the electron supply layer 50 instead of the AlN layer.

In this regard, the thickness of the AlₓGa₁₋ₓN layer (0.6≦x<1) depends on x. In order to increase 2DEG density, it is preferable that the thickness of the AlₓGa₁₋ₓN layer (0.6≦x<1) as the electron supply layer 50 is thicker than the thickness when the AlN layer is used as the electron supply layer 50. The difference between lattice constants of AlₓGa₁₋ₓN and GaN is smaller than the difference between lattice constants of AlN and GaN, and therefore the critical thickness of the AlₓGa₁₋ₓN layer is thicker than AlN layer. Thus, the AlₓGa₁₋ₓN layer can be formed to be thicker than or equal to the thickness of the AlN layer.

As described above, according to the first embodiment of the present invention, the heterojunction field effect transistor includes the AlN layer or the AlₓGa₁₋ₓN layer (0.6≦x<1) as the electron supply layer 50, and therefore it becomes possible to obtain 2DEG density which is higher than that when the conventional AlₓGa₁₋ₓN layer (for example, x=0.25) is used. As a result, it becomes possible to reduce the thickness of the electron supply layer 50. Therefore, the aspect ratio can be increased even in the short gate region, and therefore the short channel effect can be prevented.

Further, according to the manufacturing method of the heterojunction field effect transistor, the cap layer 60 (the GaN layer) is formed following the formation of the electron supply layer 50 (the AlN layer or AlₓGa₁₋ₓN layer (0.6≦x<1)) using the MOCVD in the same equipment, and therefore it becomes possible to prevent the occurrence of cracks on the electron supply layer 50.

### Second Embodiment

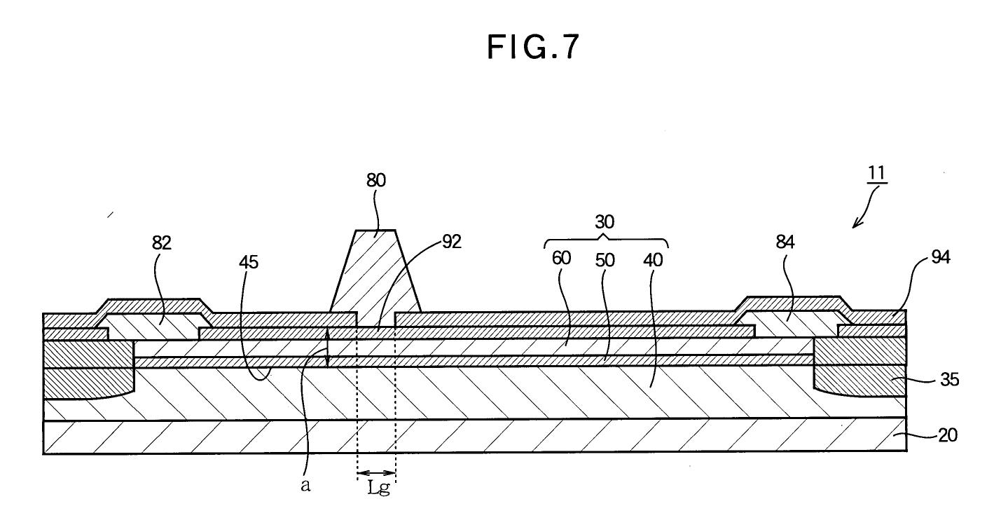

Next, a heterojunction field effect transistor according to the second embodiment of the present invention will be described with reference to FIG. 7. FIG. 7 is a sectional view schematically showing the heterojunction field effect transistor according to the second embodiment.

The heterojunction field effect transistor 11 according to the second embodiment has a MIS (Metal Insulator Semiconductor) structure in which a silicon nitride (SiN) film is formed as a gate insulation film 92 on the laminated body 30, and a gate electrode 80 is formed on the gate insulation film 92. A surface protection film 94 is formed on the gate insulation film 92. The field effect transistor having the MIS structure is called as MIS-FET. The structure of the laminated body 30 is the same as that of the first embodiment.

By employing the MIS structure, the gate leak current can be restricted. Even in the case where the silicon nitride film having the thickness of 14 nm is formed as the gate insulation film 92, when the thickness of the electron supply layer 50 is 2.4 nm and the thickness of the cap layer 60 is 3.3 nm, the active layer thickness a (i.e., the distance from the gate electrode 80 to the heterointerface 45) is thinner than or equal to 20 nm. Therefore, the aspect ratio can be maintained to be greater than or equal to 5 even when the gate length is 100 nm.

The conventional GaN-based MISFET uses the electron supply layer of AlGaN, and therefore the aspect ratio is small. For example, if the thickness of the electron supply layer of AlₓGa₁₋ₓN (x=0.25) is 25 nm and the thickness of the silicon nitride film is 14 nm, the active layer thickness a (i.e., the distance from the gate electrode to the heterointerface) is 39 nm, and therefore the aspect ratio is reduced to 2.5 when the gate length is 0.1 μm.

In contrast, in a configuration using 2DEG formed between the AlN/GaN heterointerface 45, the thickness of the electron supply layer 50 (the AlN layer) is, for example, 2.4 nm, and the thickness of the cap layer 60 (the second GaN layer) is, for example, 3.3 nm. Therefore, the aspect ratio is greater than or equal to 5 even when the thickness of the silicon nitride film is 14 nm.

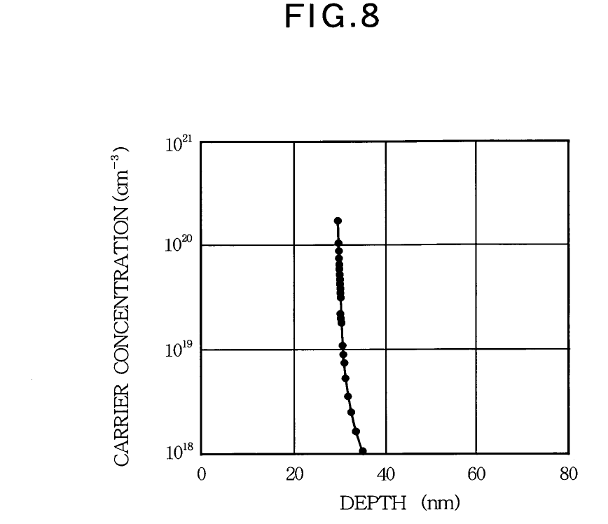

FIG. 8 shows a measurement result of carrier concentration measured by C-V method using mercury probe. In FIG. 8, the horizontal axis represents a depth (unit: nm) with respect to the bottom surface of the gate electrode 80 (i.e., the upper surface of the gate insulation film 92). The vertical axis represents carrier concentration (unit: cm⁻³). FIG. 8 shows the measurement result in the case where the thickness of the electron supply layer 50 (the AlN layer) is 2.4 nm, the cap layer 60 (the GaN layer) is 3.3 nm, and the thickness of the silicon oxide film (the gate insulation film 92) is 14 nm. The existence of carrier having the concentration of 1.75×10²⁰ cm⁻³ is recognized at the depth of 30 nm.

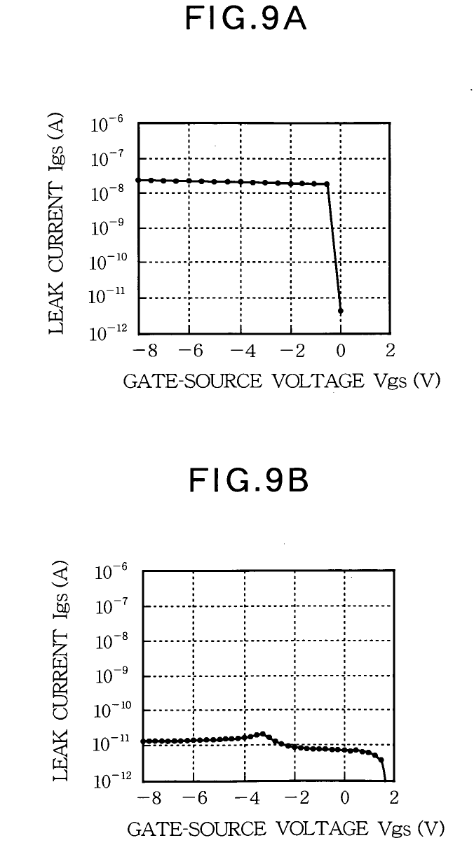

Next, the gate leak current will be described with reference to FIGS. 9A and 9B. FIG. 9A shows characteristics of gate leak current of the heterojunction field effect transistor according to the first embodiment having been described with reference to FIG. 1. FIG. 9B shows characteristics of gate leak current of the heterojunction field effect transistor according to the second embodiment having been described with reference to FIG. 7. In each of FIGS. 9A and 9B, the horizontal axis represents gate-source voltage Vgs (unit: V), and the vertical axis represents leak current Ids (unit: A) flowing between the gate electrode and the source electrode.

As shown in FIGS. 9A and 9B, the leak current Ids is approximately in a range from 1×10⁻⁸ to 1×10⁻⁷ A in the first embodiment, while the leak current Ids is approximately in a range from 1×10⁻¹² to 1×10⁻¹¹ A in the second embodiment. From these results, it is understood that, in the second embodiment, the leak current is reduced to approximately 1/1000 of the leak current in the first embodiment.

The silicon nitride film can be formed by arbitrary suitable method such as plasma CVD, thermal CVD or the like. However, it is preferable to form the silicon nitride film using the MOCVD method following the formation of the laminated body 30 including the channel layer 40, the electron supply layer 50 and the cap layer 60 in the same equipment. To be more specific, the silicon nitride film is preferably formed in the CVD equipment at the growing temperature of 850° C. while introducing NH₃ gas and silane (SiH₄) gas respectively at flow rates of 4 slm and 100 sccm.

By forming the gate insulation film 92 (the silicon nitride film) following the formation of the laminated body 30 (the channel layer, the electron supply layer and the cap layer) in the same equipment, an excellent condition of the SiN/GaN interface can be obtained. As a result, in the operation of the MISFET, interface energy level can be reduced, and current collapse due to interface energy level can be restricted, with the result that gate withstand voltage can be enhanced.

In this regard, the heterojunction field effect transistor of the second embodiment can have an AlₓGa₁₋ₓN (0.6≦x<1) layer as the electron supply layer 50 instead of the AlN layer as was described in the first embodiment.

### Third Embodiment

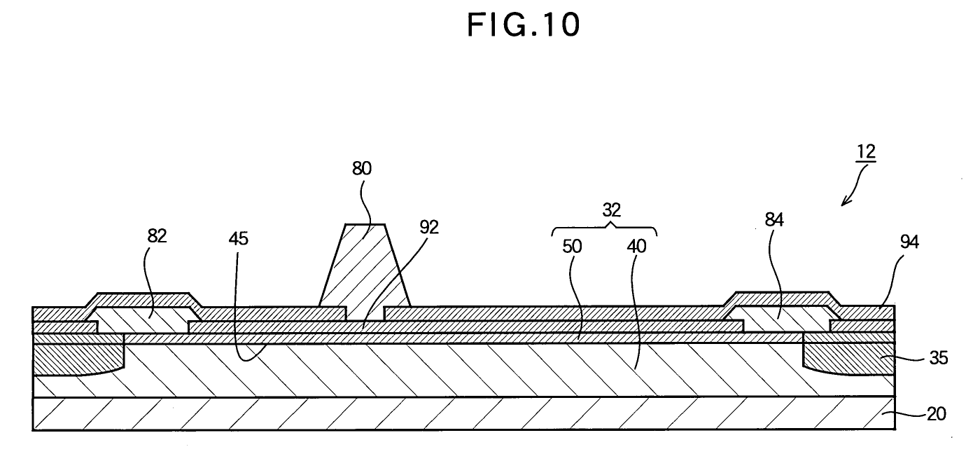

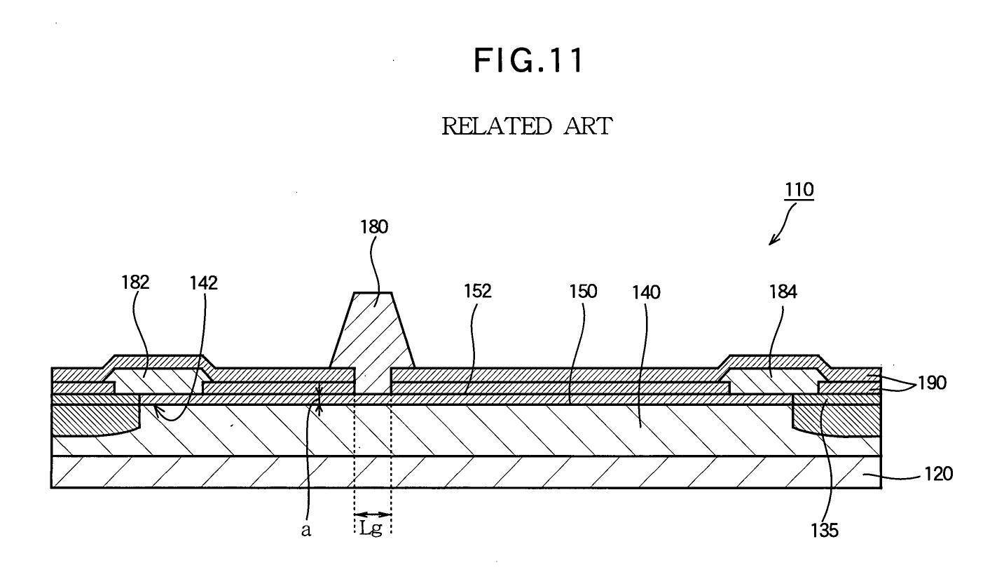

Next, a heterojunction field effect transistor according to the third embodiment will be described. FIG. 10 is a sectional view schematically showing the heterojunction field effect transistor according to the third embodiment.

The heterojunction field effect transistor 12 according to the third embodiment includes a laminated body 32 in which the channel layer 40 (the GaN layer) and the electron supply layer 50 (the AlN layer) are laminated in this order on the substrate 20. Two dimensional electron gas (2DEG) is formed in the AlN/GaN heterointerface 45 between the channel layer 40 and the electron supply layer 50.

In this third embodiment, a silicon nitride film as a gate insulation film 92 is formed on the electron supply layer 50 (the AlN layer). A surface protection film 94 is formed on the gate insulation film 92. The channel layer 40 (the GaN layer) and the electron supply layer 50 are formed using the MOCVD method as described in the second embodiment. The silicon nitride film (the gate insulation film 92) is formed following the formation of the electron supply layer 50 (the AlN layer) in the same MOCVD equipment.

As a result, the formation of the silicon nitride film (the gate insulation film 92) is performed without exposing the surface of the electron supply layer 50 (the AlN layer) to the atmosphere. Therefore, it becomes possible to prevent the surface oxidation of the electron supply layer 50 and to prevent the occurrence of cracks due to the surface oxidation.

In this regard, the heterojunction field effect transistor 12 of the third embodiment can have AlₓGa₁₋ₓN (0.6≦x<1) layer as the electron supply layer 50 instead of the AlN layer as was described in the first and second embodiments.

As described above, according to the embodiments of the present invention, since the heterojunction field effect transistor includes the electron supply layer 50 of AlN or AlₓGa₁₋ₓN (0.6≦x<1), 2DEG density can be higher than that when the conventional AlₓGa₁₋ₓN (for example, x=0.25) is used as the electron supply layer 50. Therefore, the thickness of the electron supply layer 50 can be thinner. Accordingly, the aspect ratio can be increased even in the short gate region, and therefore the short channel effect can be prevented.

Moreover, since the cap layer 60 of GaN or the gate insulation film 92 of silicon nitride is formed following the formation of the electron supply layer 50 of AlN or AlₓGa₁₋ₓN (0.6≦x<1) using the MOCVD method in the same equipment, it becomes possible to prevent the occurrence of cracks on the electron supply layer 50 (AlN layer or AlₓGa₁₋ₓN layer) due to surface oxidation.

While the preferred embodiments of the present invention have been illustrated in detail, it should be apparent that modifications and improvements may be made to the invention without departing from the spirit and scope of the invention as described in the following claims.

What is claimed is:

1. A heterojunction field effect transistor comprising:
a laminated body comprising:
a channel layer of GaN;
an electron supply layer of AlN or AlₓGa₁₋ₓN (0.6≦x<1) formed on said channel layer, and
a cap layer of GaN formed on said electron supply layer.

2. The heterojunction field effect transistor according to claim 1, further comprising a control electrode, a first main electrode and a second main electrode provided on said laminated body.

3. The heterojunction field effect transistor according to claim 2, further comprising a gate insulation film provided between said laminated body and said control electrode.

4. A manufacturing method of a heterojunction field effect transistor comprising the steps of:
forming a channel layer of GaN on a substrate;
forming an electron supply layer of AlN or AlₓGa₁₋ₓN (0.6≦x<1) on said channel layer, and
forming a cap layer of GaN on said electron supply layer,
wherein said forming steps of said channel layer, said electron supply layer and said cap layer are performed using metal organic chemical vapor deposition method in the same equipment.

5. A manufacturing method of a heterojunction field effect transistor comprising the steps of:
forming a channel layer of GaN on a substrate;
forming an electron supply layer of AlN or AlₓGa₁₋ₓN (0.6≦x<1) on said channel layer, and
forming a gate insulation film of silicon nitride on said electron supply layer,
wherein said forming steps of said channel layer, said electron supply layer and said gate insulation film are performed using metal organic chemical vapor deposition method in the same equipment.
